(19) United States
(12) Patent Application Publication
(10) Pub. No.: US 2008/0018503 A1
(43) Pub. Date: Jan. 24, 2008

(54) Method and apparatus for encoding/playing multimedia contents

(75) Inventors: Sangkyun Kim, Yongin-si (KR); Jiyeun Kim, Seoul (KR); Yongman Ro, Daejeon-si (KR); Seungji Yang, Wonju-si (KR)

Correspondence Address: STAAS & HALSEY LLP, SUITE 700, 1201 NEW YORK AVENUE, N.W., WASHINGTON, DC, 20005, US

(73) Assignees: SAMSUNG ELECTRONICS CO., LTD., Suwon-si (KR); RESEARCH & INDUSTRIAL COOPERATION GROUP, Daejeon-si (KR)

(21) Appl. No.: 11/489,452

(22) Filed: Jul. 20, 2006

Related U.S. Application Data
(60) Provisional application No. 60/700,737, filed on Jul. 20, 2005.

(30) Foreign Application Priority Data
May 30, 2006 (KR) 10-2006-0049042

(51) Int. Cl. H03M 7/00

(52) U.S. Cl. 341/50

(57) ABSTRACT

A method and an apparatus for encoding and playing multimedia contents are provided. The method includes: separating media data and metadata from the multimedia contents; creating multimedia application format (MAF) metadata by using the separated metadata, the format of the MAF metadata being predetermined; and encoding the media data and the MAF metadata to generate an MAF file including a header, the MAF metadata, and the media data, the header having information that provides a location of the media data. Accordingly, in a process of integrating digital photos and other multimedia content files into one file in the application file format MAF, visual feature information obtained from photo data and the contents of the photo images, and a variety of hint feature information for effective indexing of photos are included as metadata and content application method tools based on the metadata are included. As a result, even when the user does not have a specific application or a function for applying metadata, general-purpose multimedia content files can be effectively used by effectively browsing the multimedia content files.

### CROSS-REFERENCE TO RELATED APPLICATIONS

This application claims the priority of U.S. Provisional Application Nos. 60/700,737, filed on Jul. 20, 2005, in the United States Patent Trademark Office, and the benefit of Korean Patent Application No. 10-2006-0049042, filed on May 30, 2006, in the Korean Intellectual Property Office, the disclosures of which are incorporated herein in their entirety by reference.

### BACKGROUND OF THE INVENTION

1. Field of the Invention

The present invention relates to processing of multimedia contents, and more particularly, to a method and an apparatus for encoding and playing multimedia contents.

2. Description of the Related Art

Moving Picture Experts Group (MPEG), which is an international standardization organization related to multimedia, has been conducting standardization of MPEG-2, MPEG-4, MPEG-7 and MPEG-21, since its first standardization of MPEG-1 in 1988. As a variety of standards have been developed in this way, a need to generate one profile by combining different standard technologies has arisen. As a step responding to this need, MPEG-A (MPEG Application: ISO/ICE 230000) multimedia application standardization activities have been carried out. Application format standardization for music contents has been performed under a name of MPEG Music Player Application Format (ISO/ICE 23000-2) and at present the standardization is in its final stage. Meanwhile, application format standardization for image contents, and photo contents in particular, has entered a fledgling stage under a name of MPEG Photo Player Application Format (ISO/IEC 23000-3).

Previously, element standards required in one single standard system are grouped as a set of function tools, and made to be one profile to support a predetermined application service. However, this method has a problem in that it is difficult to satisfy a variety of technological requirements of industrial fields with a single standard. In a multimedia application format (MAF) for which standardization has been newly conducted, non-MPEG standards as well as the conventional MPEG standards are also combined so that the utilization value of the standard can be enhanced by actively responding to the demand of the industrial fields. The major purpose of the MAF standardization is to provide opportunities that MPEG technologies can be easily used in industrial fields. In this way, already verified standard technologies can be easily combined without any further efforts to set up a separate standard for application services required in the industrial fields.

At present, a music MAF is in a final draft international standard (FDIS) state and the standardization is in an almost final stage. Accordingly, the function of an MP3 player which previously performed only a playback function can be expanded and thus the MP3 player can automatically classify music files by genre and reproduce music files, or show the lyrics or browse album jacket photos related to music while the music is reproduced. This means that a file format in which users can receive more improved music services has been prepared. In particular, recently, the MP3 player has been mounted on a mobile phone, a game console (e.g., Sony's PSP), or a portable multimedia player (PMP) and has gained popularities among consumers. Therefore, a music player with enhanced functions using the MAF is expected to be commercialized soon.

Meanwhile, standardization of a photo MAF is in its fledgling stage. Like the MP3 music, photo data (in general, Joint Photographic Experts Group (JPEG) data) obtained through a digital camera has been rapidly increasing with the steady growth of the digital camera market. As media (memory cards) for storing photo data have been evolving toward a smaller size and higher integration, hundreds of photos can be stored in one memory card now. However, in proportion to the increasing amount of the photos, the difficulties that users are experiencing have also been increasing.

In the recent several years, the MPEG has standardized element technologies required for content-based retrieval and/or indexing as descriptors and description schemes under the name of MPEG-7. A descriptor defines a method of extracting and expressing content-based feature values, such as texture, shape, and motions of an image, and a description scheme defines the relations between two or more descriptors and a description scheme in order to model digital contents, and defines how to express data. Though the usefulness of MPEG-7 has been proved through a great number of researches, lack of an appropriate application format has prevented utilization of the MPEG-7 in the industrial fields. In order to solve this problem, the photo MAF is aimed to standardize a new application format which combines photo digital contents and related metadata in one file.

Also, the MPEG is standardizing a multimedia integration framework under the name of MPEG-21. That is, in order to solve potential problems, including compatibility among content expression methods, methods of network transmission, and compatibility among terminals, caused by individual fundamental structures for transmission and use of multimedia contents and individual management systems, the MPEG is suggesting a new standard enabling transparent access, use, process, and reuse of multimedia contents through a variety of networks and devices. The MPEG-21 includes declaration, adaptation, and processing of digital items (multimedia contents+metadata).

However, the problem of how to interoperate the technologies of the MPEG-7 and MPEG-21 with the MAF has yet to be solved.

### SUMMARY OF THE INVENTION

Additional aspects, features, and/or advantages of the invention will be set forth in part in the description which follows and, in part, will be apparent from the description, or may be learned by practice of the invention.

The present invention provides a method and apparatus for encoding multimedia contents in which in order to allow a user to effectively browse or share photos, photo data, visual feature information obtained from the contents of photo images, and a variety of hint feature information for effective indexing of photos are used as metadata and encoded into a multimedia application format (MAF) file.

The present invention also provides a method and an apparatus for decoding and reproducing MAF files so as to allow a user to effectively browse the MAF files.

The present invention also provides a new MAF combining metadata related to digital photo data.

According to an aspect of the present invention, there is provided a method of encoding multimedia contents including: separating media data and metadata from multimedia contents; creating metadata complying with a predetermined multimedia application format (MAF) by using the separated metadata; and encoding the media data and the metadata complying with the multimedia application format, and thus creating an MAF file including a header containing information indicating a location of the media data, the metadata and the media data.

The method further may include acquiring multimedia data from a multimedia device before the separating of the media data and the metadata from the multimedia contents.

The acquiring of the multimedia contents may include acquiring photo data from a multimedia apparatus and a photo content acquiring apparatus, and the multimedia contents comprise music and video data related to the photos.

The separating of media data and metadata from multimedia contents comprises extracting information required to generate metadata related to a corresponding media content by parsing exchangeable image file format (Exif) metadata or decoding a joint photographic experts group (JPEG) image included in the multimedia contents.

The metadata comprises Exif metadata of a JPEG photo file, ID3 metadata of an MP3 music file, and compression related metadata of an MPEG video file.

The creating of metadata complying with a predetermined MAF may include creating the metadata complying with an MPEG standard from the separated metadata, or creating the metadata complying with an MPEG standard by extracting and creating metadata from the media content by using an MPEG-based standardized description tool.

The metadata complying with an MPEG standard may include MPEG-7 metadata for the media content itself, and MPEG-21 metadata for declaration, adaptation conversion, and distribution of the media content.

The MPEG-7 metadata may include MPEG-7 descriptors of metadata for media content-based feature values, MPEG-7 semantic descriptors of metadata for media semantic information, and MPEG-7 media information/creation descriptors of media creation information.

The MPEG-7 media information/creation descriptors may include media albuming hints.

The media albuming hints may include acquisition hints representing camera information and photographing information for taking a picture, perception hints representing person perceptual features for photo contents, subject hints representing information of a person in a photo, view hints representing camera view information, and popularity representing popularity information of a photo.

The acquisition hints representing camera information and photographing information of a picture may include: at least one of photographer information, photographing time information, camera manufacturer information, camera model information, shutter speed information, color mode information, ISO information for film sensitivity, flash information regarding whether a flash is used or not, aperture information detailing an F-number of the iris of a camera lens, optical zooming distance information, focal length information, distance information of a distance between a focused object and the camera, GPS information for location of photo capture, orientation information representing a camera direction that is a location of a first pixel in an image, sound information for recoded voice or sound, and thumbnail mage information for fast browsing of stored thumbnails in the camera; and information regarding whether corresponding photo data includes Exif information as metadata or not.

The subject hints representing person information of a photo may include an item representing the number of persons in a photo, an item representing face location information and information of clothes worn by each person of a photo, and an item representing a relationship between persons of a photo.

The view hints representing camera view information may include an item representing whether a main portion of a photo is a background or a foreground, an item representing a portion location corresponding to a middle of the photo, and an item representing a portion location corresponding to a background.

The MPEG-21 metadata may include an MPEG-21 DID (digital item declaration) description that is metadata related to a DID, an MPEG-21 DIA (digital item adaptation) description that is metadata for a DIA, and rights expression data that is metadata regarding rights/copyrights of contents. The rights expression data may include a browsing permission that is metadata of permission information of browsing photo contents, and an editing permission that is metadata of permission information of editing photo contents.

The method further may include creating MAF application method data, wherein the encoding of the media data and the MAF metadata may include creating an MAF file including a header, the MAF metadata, and the media data by using the media data, the MAF metadata, and the MAF application method data.

The MAF application method data may include: an MPEG-4 scene descriptor describing an albuming method defined by a media albuming tool, and a procedure and a method for media playing; and an MPEG-21 digital item processing descriptor processing digital items according to an intended format and procedure.

The MAF file in the encoding of the media data and the predetermined MAF metadata may include a single track MAF having metadata corresponding to one media content as a basic component, the single track MAF including an MAF header for a corresponding track, MPEG metadata, and media data.

The MAF file in the encoding of the media data and the predetermined MAF metadata may include a multiple track MAF including more than one single track MAF, an MAF header for the multiple track, and MPEG metadata for the multiple track. The MAF file in the encoding of the media data and the predetermined MAF metadata may include a multiple track MAF having more than one single track MAF, an MAF header for the multiple track, MPEG metadata for the multiple track, and MAF file application method data.

The MPEG-7 semantic descriptors extract and generate semantic information of the multimedia contents using albuming hints. The extracting of the semantic information may include performing media albuming by using media albuming hints or combining the media albuming hints and the contents-based feature values.

According to another aspect of the present invention, there is provided an apparatus for encoding multimedia contents, the apparatus including: a pre-processing unit separating media data and metadata from multimedia contents; a media metadata creation unit creating MAF metadata by using the separated metadata, the format of the MAF metadata being predetermined; and an encoding unit encoding the media data and the MAF metadata to generate an MAF file including a header, the MAF metadata, and the media data, the header having information that provides a location of the media data.

The multimedia contents may include photo data acquired from a photo contents imaging device, and the photo data and the multimedia contents may include music and video related to the photo data acquired from the multimedia device.

The pre-processing unit extracts information to generate the MAF metadata of a corresponding media data by parsing Exif metadata in the multimedia contents or decoding a JPEG image. The media metadata creation unit creates the MAF metadata compatible with MPEG standards by using the separated metadata, or by extracting and creating metadata from media data using an MPEG-based standardized description tool.

The metadata compatible with the MPEG standard may include MPEG-7 metadata for the media data, and MPEG-21 metadata for declaration, adaptation conversion, and distribution of media.

The MPEG-7 metadata may include MPEG-7 descriptors of metadata for media contents-based feature values, MPEG-7 semantic descriptors of metadata for media semantic information, and MPEG-7 media information/creation descriptors of media creation information.

The MPEG-7 media information/creation descriptors may include media albuming hints.

The MPEG-21 metadata may include an MPEG-21 DID description that is metadata related to a DID, an MPEG-21 DIA description that is metadata for a DIA, and rights expression data that is metadata regarding rights/copyrights of contents.

The apparatus may include an application method data creation unit that creates MAF application method data, wherein the encoding unit creates an MAF file including a header, metadata, and media data using the media data, the MAF metadata, and the MAF application method data, the header having information that provides the location of the media data.

The MAF application method data may include: an MPEG-4 scene description describing an albuming method defined by a media albuming tool, and a procedure and a method for media playing; and an MPEG-21 digital item processing (DIP) descriptor for DIP according to an intended format and procedure.

The MAF file may include single track MAF having metadata corresponding to one media content as a basic component, the single track MAF including an MAF header for the corresponding track, MPEG metadata, and media data. The MAF file in the MAF encoding unit may include a multiple track of the MAF file including more than one single track MAF, an MAF header for the corresponding multiple track, and MPEG metadata for the corresponding multiple track.

The MAF file may include a multiple track of the MAF including more than one single track MAF, an MAF header for the corresponding multiple track, MPEG metadata for the corresponding multiple track, and MAF file application method data.

According to another aspect of the present invention, there is provided a method of playing multimedia contents, the method including: decoding an MAF file including a header and application data to extract media data, media metadata, and application data, the header having information that provides the location of media data, the application data providing media application method information having at least one single track with media data and media metadata; and playing the multimedia contents using the extracted metadata and the application data.

The playing of the multimedia contents may include using media metadata tools for processing media metadata and application method tools for browsing the media contents through metadata and application data.

According to another aspect of the present invention, there is provided an apparatus of playing multimedia contents, the apparatus including: an MAF decoding unit decoding an MAF file including a header having information that provides a location of media data, at least one single track having media data and media metadata, and application data representing media application method information to extract the media data, media metadata, and the application data; and an MAF playing unit playing the multimedia contents by using the extracted metadata and application data.

The playing of the multimedia contents may include using media metadata tools for processing media metadata and application method tools for browsing the media contents through metadata and application data.

The MAF file may include a multiple track of the MAF having more than one single track MAF, an MAF header for the corresponding multiple track, and MPEG metadata for the corresponding multiple track.

An MAF may include a multiple track of the MAF having more than one single track MAF, an MAF header for the corresponding multiple track, and MPEG metadata for the corresponding multiple track.

The MAF further may include application method data for an application method of an MAF file.

According to still another aspect of the present invention, there is provided a computer readable recording medium having embodied thereon a computer program for executing the methods.

### BRIEF DESCRIPTION OF THE DRAWINGS

These and/or other aspects, features, and advantages of the invention will become apparent and more readily appreciated from the following description of the embodiments, taken in conjunction with the accompanying drawings of which:

FIG. 1 is a block diagram of an overall system configuration according to an embodiment of the present invention;

FIG. 2 is a flowchart illustrating a method of encoding and decoding multimedia contents after effectively constituting a photo multimedia application format (MAF) according to an embodiment of the present invention;

FIG. 3 is a block diagram of components and structures in metadata according to an embodiment of the present invention;

FIG. 4 is a block diagram of a description structure of media albuming hints according to an embodiment of the present invention;

FIG. 5 is a block diagram of a description structure of acquisition hints included in media albuming hints according to an embodiment of the present invention;

FIG. 6 is a block diagram of a description structure of perception hints included in media albuming hints according to an embodiment of the present invention;

FIG. 7 is a block diagram of a description structure of subject hints that represents person information according to an embodiment of the present invention;

FIG. 8 is a block diagram of a description structure of view hints of a photo according to an embodiment of the present invention;

FIG. 9 is a block diagram of acquisition hints expressed in XML schema according to an embodiment of the present invention;

FIG. 10 is a block diagram of perception hints expressed in XML schema according to an embodiment of the present invention;

FIG. 11 is a block diagram of subject hints expressed in XML schema according to an embodiment of the present invention;

FIG. 12 is a block diagram of view hints expressed in XML schema according to an embodiment of the present invention;

FIG. 13 is block diagram of a structure of media application method data according to an embodiment of the present invention;

FIG. 14 is a block diagram of a structure of an MAF file according to an embodiment of the present invention; and

FIG. 15 is a block diagram of a structure of an MAF file according to another embodiment of the present invention

### DETAILED DESCRIPTION OF THE PREFERRED EMBODIMENTS

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

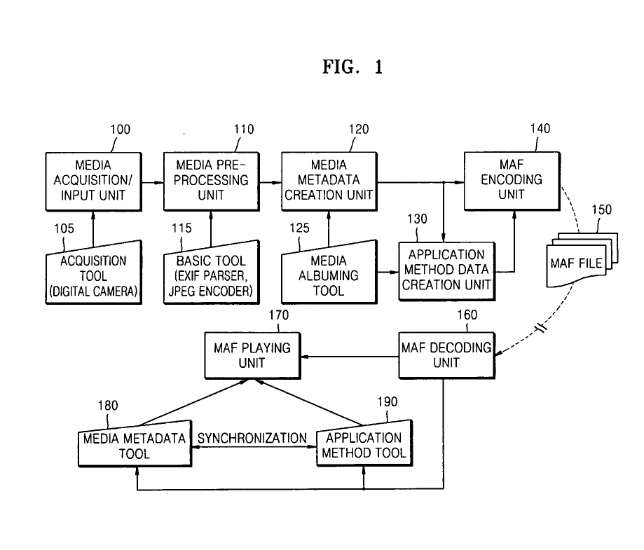

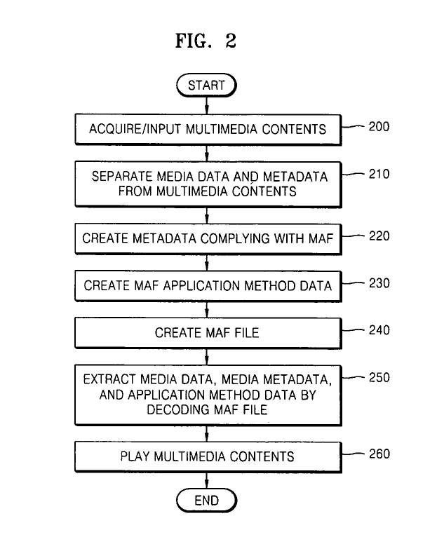

FIG. 1 is a block diagram of an overall system configuration according to an embodiment of the present invention. FIG. 2 is a flowchart illustrating a method of encoding and decoding multimedia contents after effectively constituting a photo multimedia application format (MAF) according to an embodiment of the present invention.

Referring to FIGS. 1 and 2, in operation S200, a media acquisition/input unit 100 acquires/receives multimedia data from a multimedia apparatus. For example, photos can be acquired by/input to the media acquisition/input unit 100 using an acquisition tool 105 such as a digital camera. Photo contents are acquired by/input to the media acquisition/input unit 100, but the acquired or input media content is not limited to photo contents. That is, various multimedia contents such as photos, music, and video can be acquired by/input to the media acquisition/input unit 100.

The acquired/input media data in the media acquisition/input unit 100 is transferred into a media pre-processing unit 110 performing basic processes related to the media. The media pre-processing unit 110 extracts basic information for creating metadata of a corresponding media by parsing exchangeable image file format (Exif) metadata in media or decoding JPEG images in operation S210. The basic information can include Exif metadata in a JPEG photo file, ID3 metadata of an MP3 music file, and compression related metadata of an MPEG video file. However, the basic information is not limited to these examples.

The basic information related to the media data processed in the media pre-processing unit 110 is transferred into a media metadata creation unit 120. In operation S220, the media metadata creation unit 120 creates metadata complying with an MPEG standard, by using the transferred basic information, or directly extracts and creates metadata from the media and creates metadata complying with the MPEG standard, by using an MPEG-based standardized description tool 125.

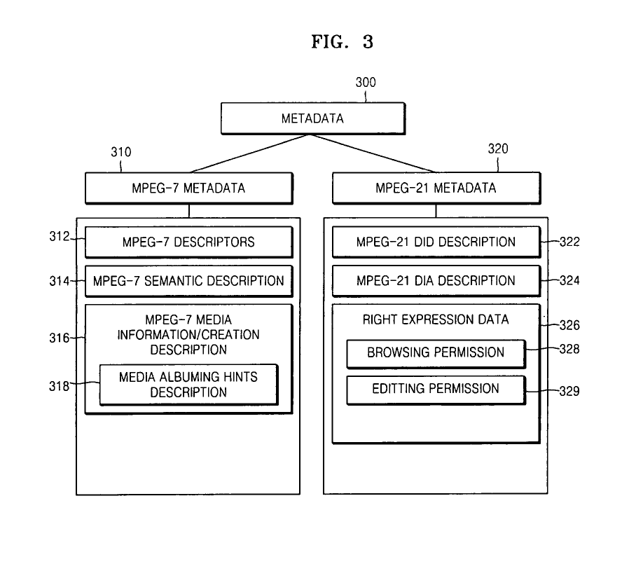

The present invention uses MPEG-7 and MPEG-21 to describe metadata according to standardized format and structure. FIG. 3 is a block diagram of components and structures in metadata according to an embodiment of the present invention.

Referring to FIG. 3, metadata 300 includes MPEG-7 metadata 310 for the media content itself, and MPEG-21 metadata 320 for declaration, administration, adaptation conversion, and distribution of the media content.

The MPEG-7 metadata 310 includes MPEG-7 descriptors 312 of metadata for media content-based feature values, an MPEG-7 semantic description 314 of media semantic metadata, and an MPEG-7 media information/creation description 316 of media creation-related metadata.

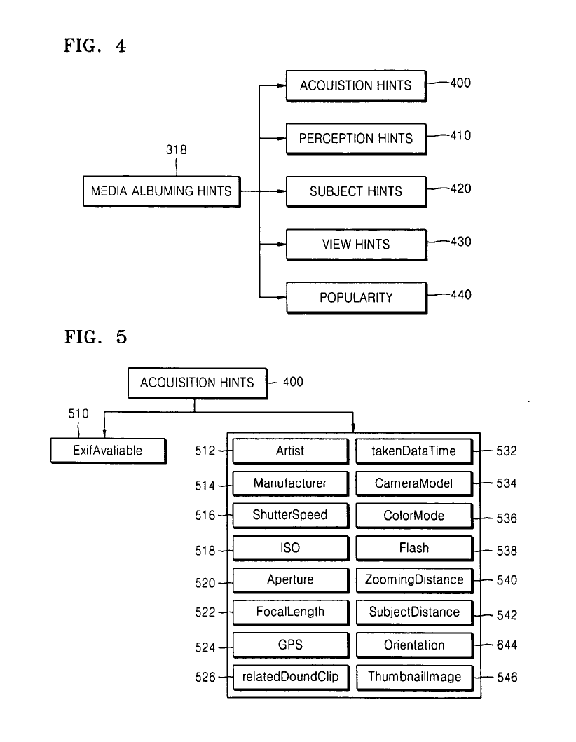

According to the present invention, the MPEG-7 media information/creation description 316 includes media albuming hints 318 in various metadata. FIG. 4 is a block diagram of a description structure of media albuming hints according to an embodiment of the present invention.

Referring to FIG. 4, the media albuming hints 318 includes acquisition hints 400 to express camera information and photographing information when a photo is taken, perception hints 410 to express perceptional characteristics of a human being in relation to the contents of a photo, subject hints 420 to express information on persons included in a photo, view hints 430 to express view information of a photo, popularity 440 to express popularity information of a photo.

FIG. 5 is a block diagram of a description structure of acquisition hints 400 to express camera information and photographing information when a photo is taken, according to an embodiment of the present invention.

Referring to FIG. 5, the acquisition hints 400 include basic photographing information and camera information, which can be used in photo albuming.

The acquisition hints 400 include information (EXIFAvailable) 510 indicating whether or not photo data includes Exif information as metadata, information (artist) 512 on the name and ID of a photographer who takes a photo, time information (takenDateTime) 532 on the time when a photo is taken, information (manufacturer) 514 on the manufacturer of the camera with which a photo is taken, camera model information (CameraModel) 534 of a camera with which a photo is taken, shutter speed information (ShutterSpeed) 516 of a shutter speed used when a photo is taken, color mode information (ColorMode) 536 of a color mode used when a photo is taken, information (ISO) 518 indicating the sensitivity of a film (in case of a digital camera, a CCD or CMOS image pickup device) when a photo is taken, information (Flash) 538 indicating whether or not a flash is used when a photo is taken, information (Aperture) 520 indicating the aperture number of a lens iris used when a photo is taken, information (ZoomingDistance) 540 indicating the optical or digital zoom distance used when a photo is taken, information (FocalLength) 522 indicating the focal length used when a photo is taken, information (SubjectDistance) 542 indicating the distance between the focused subject and the camera when a photo is taken, GPS information (GPS) 524 on a place where a photo is taken, information (Orientation) 544 indicating the orientation of a first pixel of a photo image as the orientation of a camera when the photo is taken, information (relatedSoundClip) 526 indicating voice or sound recorded together when a photo is taken, and information (ThumbnailImage) 546 indicating a thumbnail image stored for high-speed browsing in a camera after a photo is taken.

The above information exists in Exif metadata, and can be used effectively for albuming of photos. If photo data includes Exif metadata, more information can be used. However, since photo data may not include Exif metadata, the important metadata is described as photo albuming hints. The description structure of the photo acquisition hint item 3520 includes includes the information items described above, but is not limited to these items.

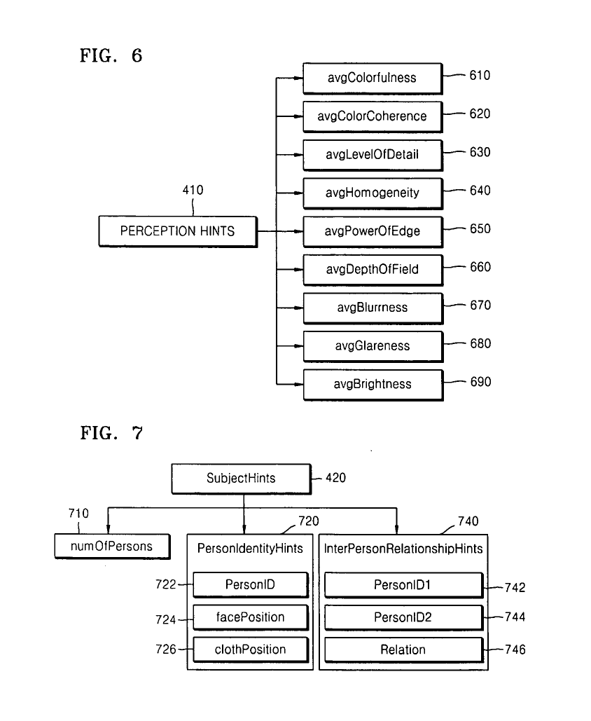

FIG. 6 is a block diagram of a description structure of perception hints 410 to express perceptional characteristics of a human being in relation to the contents of a photo, according to an embodiment of the present invention.

Referring to FIG. 6, the description structure of perception hints 410 includes information on the characteristic that a person intuitively perceives the contents of a photo. A feeling most strongly felt by a person exists when the person watches a photo.

Referring to FIG. 6, the description structure of the perception hints 410 include an item (avgcolorfulness) 610 indicating the colorfulness of the color tone expression of a photo, an item (avgColorCoherence) 620 indicating the color coherence of the entire color tone appearing in a photo, an item (avgLevelOfDetail) 630 indicating the detailedness of the contents of a photo, an item (avgHomogenity) 640 indicating the homogeneity of texture information of the contents of a photo, an item (avgPowerOfEdge) 650 indicating the robustness of edge information of the contents of a photo, an item (avgDepthOfField) 660 indicating the depth of the focus of a camera in relation to the contents of a photo, an item (avgBlurrness) 670 indicating the blurness of a photo caused by shaking of a camera generally due to a slow shutter speed, an item (avgGlareness) 680 indicating the degree that the contents of a photo are affected by a very bright flash light or a very bright external light source when the photo is taken, and an item (avgBrightness) 690 indicating information on the brightness of an entire photo.

The item (avgcolorfulness) 610 indicating the colorfulness of the color tone expression of a photo can be measured after normalizing the histogram heights of each RGB color value and the distribution value the entire color values from a color histogram, or by using the distribution value of a color measured using a CIE L*u*v color space. However, the method of measuring the item 610 indicating the colorfulness is not limited to these methods.

The item (avgColorCoherence) 620 indicating the color coherence of the entire color tone appearing in a photo can be measured by using a dominant color descriptor among the MPEG-7 visual descriptors, and can be measured by normalizing the histogram heights of each color value and the distribution value the entire color values from a color histogram. However, the method of measuring the item 620 indicating the color coherence of the entire color tone appearing in a photo is not limited to these methods.

The item (avgLevelOfDetail) 630 indicating the detailedness of the contents of a photo can be measured by using an entropy measured from the pixel information of the photo, or by using an isopreference curve that is an element for determining the actual complexity of a photo, or by using a relative measurement method in which compression ratios are compared when compressions are performed under identical conditions, including the same image sizes, and quantization steps. However, the method of measuring the item 630 indicating the detailedness of contents of a photo is not limited to these methods.

The item (avgHomogenity) 640 indicating the homogeneity of texture information of the contents of a photo can be measured by using the regularity, direction and scale of texture from feature values of a texture browsing descriptor among the MPEG-7 visual descriptors. However, the method of measuring the item 640 indicating the homogeneity of texture information of the contents of a photo is not limited to this method.

The item (avgPowerOfEdge) 650 indicating the robustness of edge information of the contents of a photo can be measured by extracting edge information from a photo and normalizing the extracted edge power. However, the method of measuring the item 650 indicating the robustness of edge information of the contents of a photo is not limited to this method.

The item (avgDepthOfField) 660 indicating the depth of the focus of a camera in relation to the contents of a photo can be measured generally by using the focal length and diameter of a camera lens, and an iris number. However, the method of measuring the item 660 indicating the depth of the focus of a camera in relation to the contents of a photo is not limited to this method.

The item (avgBlurrness) 670 indicating the blurriness of a photo caused by shaking of a camera generally due to a slow shutter speed can be measured by using the edge power of the contents of the photo. However, the method of measuring the item 670 indicating the blurriness of a photo caused by shaking of a camera due to a slow shutter speed is not limited to this method.

The item (avgGlareness) 680 indicating the degree that the contents of a photo are affected by a very bright external light source is a value indicating a case where a light source having a greater amount of light than a threshold value is photographed in a part of a photo or in the entire photo, that is, a case of excessive exposure, and can be measured by using the brightness of the pixel value of the photo. However, the method of measuring the item 680 indicating the degree that the contents of a photo are affected by a very bright external light source is not limited to this method.

The item (avgBrightness) 690 indicating information on the brightness of an entire photo can be measured by using the brightness of the pixel value of the photo. However, the method of measuring the item 690 indicating information on the brightness of an entire photo is not limited to this method.

FIG. 7 is a block diagram of a description structure of subject hints 420 to express person information according to an embodiment of the present invention.

Referring to FIG. 7, the subject hints 420 include an item (numOfPersons) 710 indicating the number of persons included in a photo, an item (PersonidentityHints) 720 indicating the position information of each person included in a photo with the position of the face of the person and the position of clothes worn by the person, and an item (InterPersonRelationshipHints) 740 indicating the relationship between persons included in a photo.

The item 720 indicating the position information of the face and clothes of each person included in a photo includes an ID (PersonlD) 722, the face position (facePosition) 724, and the position of clothes (clothPosition) 726 of the person.

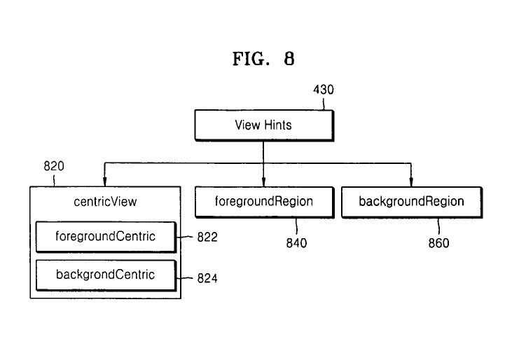

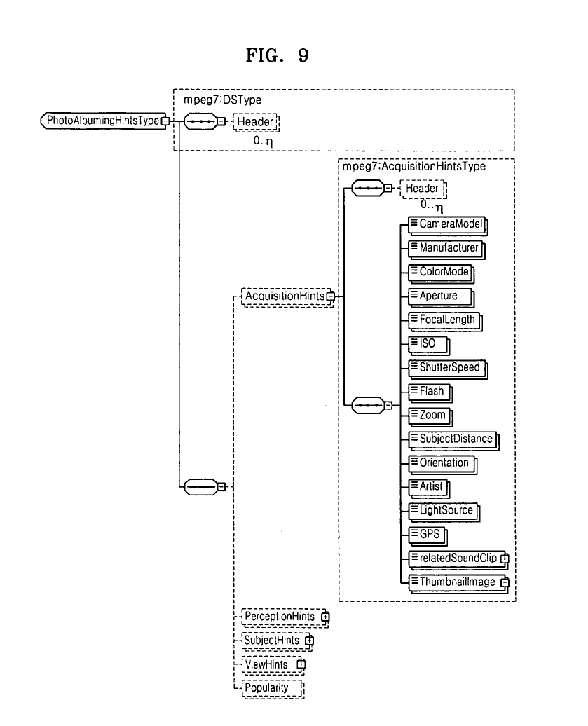

FIG. 8 is a block diagram of a description structure of view hints 430 in a photo according to an embodiment of the present invention. Referring to FIG. 8, the view hints 430 include an item (centricview) 820 indicating whether the major part expressed in a photo is a background or a foreground, an item (foregroundRegion) 840 indicating the position of a part corresponding to the foreground of a photo in the contents expressed in the photo, an item (backgroundRegion) 860 indicating the position of a part corresponding to the background of a photo.

The following table 1 shows description structures, which express hint items required for photo albuming among hint items required for effective multimedia albuming, expressed in an extensible markup language (XML) format.

```
TABLE 1
<complexType name=“PhotoAlbumingHintsType”>
    <complexContent>
        <extension base=“mpeg7:DSType”>
            <sequence>
                <element name=“AcquisitionHints”
type=“mpeg7:AcquisitionHintsType” minOccurs=“0”/>
                <element name=“PerceptionHints”
type=“mpeg7:PerceptionHintsType” minOccurs=“0”/>
                <element name=“SubjectHints”
                type=“mpeg7:SubjectHintsType” minOccurs=“0”/>
                <element name=“ViewHints”
                type=“mpeg7:ViewHintsType” minOccurs=“0”/>
                <element name=“Popularity”
                type=“mpeg7:zeroToOneType” minOccurs=“0”/>
            </sequence>
        </extension>
    </complexContent>
</complexType>
```

The following table 2 shows the description structure of the photo acquisition hints indicating camera information and photographing information when a photo is taken, among hint items required for effective photo albuming, expressed in an XML format. FIG. 9 is a block diagram of acquisition hints expressed in XML schema according to an embodiment of the present invention.

```
TABLE 2
<complexType name=“AcquisitionHintsType”>
  <complexContent>
    <extension base=“mpeg7:DSType”>
      <sequence>
        <element name=“CameraModel” type=“mpeg7:TextualType”/>
        <element name=“Manufacturer” type=“mpeg7:TextualType”/>
        <element name=“ColorMode” type=“mpeg7:TextualType”/>
        <element name=“Aperture” type=“nonNegativeInteger”/>
        <element name=“FocalLength” type=“nonNegativeInteger”/>
        <element name=“ISO” type=“nonNegativeInteger”/>
        <element name=“ShutterSpeed” type=“nonNegativeInteger”/>
        <element name=“Flash” type=“boolean”/>
        <element name=“Zoom” type=“nonNegativeInteger”/>
        <element name=“SubjectDistance” type=“nonNegativeInteger”/>
        <element name=“Orientation” type=“mpeg7:TextualType”/>
        <element name=“Artist” type=“mpeg7:TextualType”/>
        <element name=“LightSource” type=“mpeg7:TextualType”/>
        <element name=“GPS” type=“mpeg7:TextualType”/>
        <element name=“relatedSoundClip”
        type=“mpeg7:MediaLocatorType”/>
        <element name=“ThumbnailImage”
        type=“mpeg7:MediaLocatorType”/>
      </sequence>
      <attribute name=“EXIFAvailable” type=“boolean”
      use=“optional”/>
    </extension>
  </complexContent>
</complexType>
```

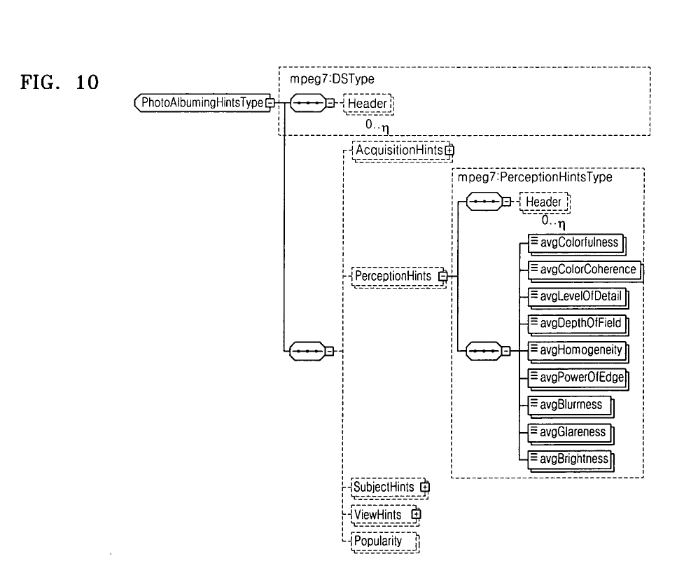

The following table 3 shows the description structure of the perception hints indicating the perceptional characteristics of a human being in relation to the contents of a photo, among hint items required for effective photo albuming, expressed in an XML format. FIG. 10 is a block diagram of perception hints expressed in XML schema according to an embodiment of the present invention.

TABLE 3

```
<complexType name=“PerceptionHintsType”>
  <complexContent>
    <extension base=“mpeg7:DSType”>
      <sequence>
        <element name=“avgColorfulness”
        type=“mpeg7:zeroToOneType”/>
        <element name=“avgColorCoherence”
        type=“mpeg7:zeroToOneType”/>
        <element name=“avgLevelOfDetail”
        type=“mpeg7:zeroToOneType”/>
        <element name=“avgDepthOfField”
        type=“mpeg7:zeroToOneType”/>
        <element name=“avgHomogeneity”
        type=“mpeg7:zeroToOneType”/>
        <element name=“avgPowerOfEdge”
        type=“mpeg7:zeroToOneType”/>
        <element name=“avgBlurrness”
        type=“mpeg7:zeroToOneType”/>
        <element name=“avgGlareness”
        type=“mpeg7:zeroToOneType”/>
        <element name=“avgBrightness”
        type=“mpeg7:zeroToOneType”/>
      </sequence>
    </extension>
  </complexContent>
</complexType>
```

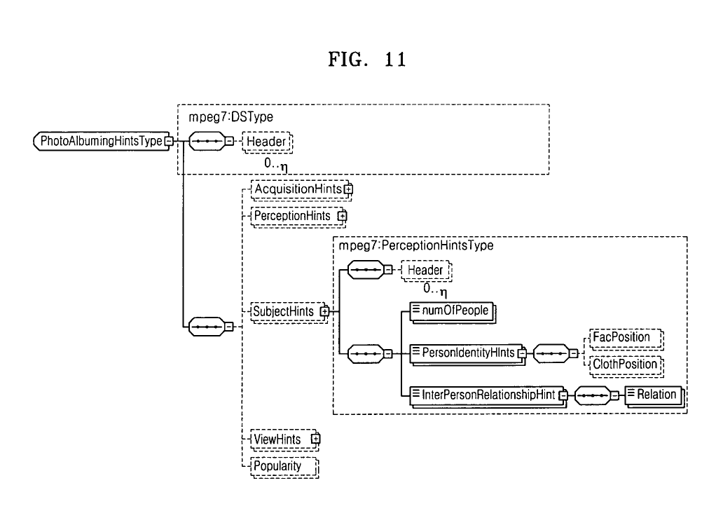

The following table 4 shows the description structure of the subject hints to indicate information on persons included in a photo, among hint items required for effective photo albuming, expressed in an XML format. FIG. 11 is a block diagram of subject hints expressed in XML schema according to an embodiment of the present invention.

```
TABLE 4
<complexType name=“SubjectHintsType”>
  <complexContent>
    <extension base=“mpeg7:DSType”>
      <sequence>
        <element name=“numOfPeople” type=“nonNegativeInteger”/>
        <element name=“PersonIdentityHints”>
          <complexType>
            <complexContent>
            <extension base=“mpeg7:DType”>
              <sequence>
                <element name=“FacePosition” minOccurs=“0”>
                  <complexType>
                    <attribute name=“xLeft” type=“nonNegativeInteger”
use=“required”/>
                    <attribute name=“xRight” type=“nonNegativeInteger”
use=“required”/>
                    <attribute name=“yDown” type=“nonNegativeInteger”
use=“required”/>
                    <attribute name=“yUp” type=“nonNegativeInteger”
use=“required”/>
                  </complexType>
                </element>
                <element name=“ClothPosition” minOccurs=“0”>
                  <complexType>
                    <attribute name=“xLeft” type=“nonNegativeInteger”
use=“required”/>
                    <attribute name=“xRight” type=“nonNegativeInteger”
use=“required”/>
                    <attribute name=“yDown” type=“nonNegativeInteger”
use=“required”/>
                    <attribute name=“yUp” type=“nonNegativeInteger”
use=“required”/>
                  </complexType>
            </element>
          </sequence>
          <attribute name=“PersonID” type=“IDREF” use=“optional”/>
        </extension>
        </complexContent>
        </complexType>
      </element>
      <element name=“InterPersonRelationshipHints”>
        <complexType>
            <complexContent>
              <extension base=“mpeg7:DType”>
                <sequence>
                  <element name=“Relation” type=“mpeg7:TextualType”/>
                </sequence>
                <attribute name=“PersonID1” type=“IDREF” use=“required”/>
                <attribute name=“PersonID2” type=“IDREF” use=“required”/>
              </extension>
            </complexContent>
          </complexType>
        </element>
      </sequence>
    </extension>
  </complexContent>
</complexType>
```

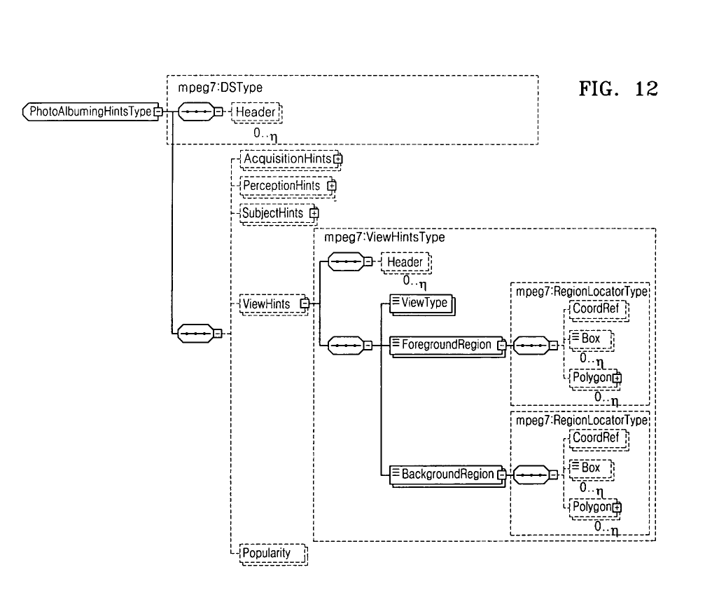

The following table 5 shows the description structure of the photo view hints indicating view information of a photo, among hint items required for effective photo albuming, expressed in an XML format. FIG. 12 is a block diagram of view hints expressed in XML schema according to an embodiment of the present invention.

TABLE 5

```
<complexType name=“ViewHintsType”>
  <complexContent>
    <extension base=“mpeg7:DSType”>
      <sequence>
        <element name=“ViewType”>
          <simpleType>
            <restriction base=“string”>
              <enumeration value=“closeUpView”/>
              <enumeration value=“perspectiveView”/>
            </restriction>
          </simpleType>
        </element>
        <element name=“ForegroundRegion”
        type=“mpeg7:RegionLocatorType”/>
        <element name=“BackgroundRegion”
        type=“mpeg7:RegionLocatorType”/>
      </sequence>
    </extension>
  </complexContent>
</complexType>
```

Referring again to FIG. 3, the MPEG-21 metadata 320 for declaration, administration, adaptation conversion, and distribution includes an MPEG-21 digital item declaration (DID) description 322 that is metadata related to a DID, an MPEG-21 digital item adaptation (DIA) description 324 that is metadata for a DIA, and rights expression data 326 that is metadata regarding rights/copyrights and using/editing of contents.

The rights expression data 326 includes browsing permission 328 that is metadata of permission information for browsing photo contents, and an editing permission 329 that is metadata of permission information for editing photo contents. The rights expression data 326 is not limited to the above metadata.

Referring again to FIG. 1, the media metadata created by the media metadata creation unit 120 is transferred into an MAF encoding unit 140.

The media albuming tool 125 includes a method, which is described below, of albuming multimedia contents using the media albuming hints description 318 of FIG. 3.

First, it is assumed that there is a set, M, of N multimedia contents. The multimedia contents may be expressed as the following equation 1:
M={m₁,m₂,m₃, . . . , m_{N}} (1)

where it is assumed that contents included in the content set M desired to be albumed have identical media format (image, audio, video).

An album hint corresponding to arbitrary j-th content mⱼ may be expressed as the following equation 2:
Hⱼ={h₁,h₂,h₃, . . . , h_{L}} (2)

where L is the number of albuming hint elements.

According to the expression method, an albuming hint set in relation to set M of N multimedia contents desired to be albumed is expressed as the following equation 3:
H={H₁,H₂,H₃, . . . , H_{N}} (3)

K content-based feature values corresponding to arbitrary j-th content mⱼ are expressed as the following equation 4:
Fⱼ={f₁,f₂,f₃, . . . , f_{K}} (4)

According to the expression method, a set of content-based feature values corresponding to set M of N multimedia contents desired to be albumed is expressed as the following equation 5:
F={F₁,F₂,F₃, . . . , F_{N}} (5)

The present invention may include two methods of media albuming by using the albuming hints. The first method performs albuming only with albuming hints. The second method uses combinations by combining albuming hints with content-based feature values.

The first albuming method using media albuming hints will now be explained. It is assumed that N multimedia contents input first are indexed or clustered as an album label set G in order to perform albuming. Album label set G composed of T labels is expressed as the following equation 6:
G={g₁,g₂,g₃, . . . , g_{T}} (6)

The method of indexing or clustering an arbitrary j-th content mⱼ only with albuming hints, as an i-th label gᵢ is expressed as the following equation 7:

$$\begin{matrix}{L}_{j} = {g}_{i} \times Φ ( {H}_{j} , {g}_{i} ) , where Φ ( {H}_{j} , {g}_{i} ) \\ = \{ \begin{matrix}1 , & {\prod }_{l = 1}^{L} B ( {h}_{l} , {g}_{i} ) = 1 \\ 0 , & otherwise\end{matrix}\end{matrix} \qquad ( 7 )$$

where function B(a,b) is a Boolean function in which when a=b, the function B is 1, or else 0, and the finally determined Lⱼ is the label of a j-th content mⱼ.

The second albuming method using media albuming hints will now be explained. First, by combining albuming hint Hⱼ of an arbitrary j-th content mⱼ with content-based feature value Fⱼ, new feature values are created. The new combined feature value Fⱼ is expressed as the following equation 8:
F_{J}′=Θ(Fⱼ, Hⱼ) (8)

where Θ is an arbitrary function for combining a content-based feature value and an albuming hint.

The new combined feature value is compared with a feature value learned with respect to label set G to obtain a similarity distance value, and a label having the highest similarity is determined as the label of the j-th content mⱼ. The method of determining the label of the j-th content mⱼ is expressed as the following equation 9:

$${L}_{j} = arg {min}_{g ∈ G} \{ D ( {F}_{j}^{′} , {F}_{G} ) \} \qquad ( 9 )$$

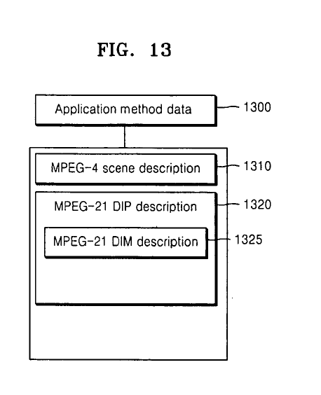

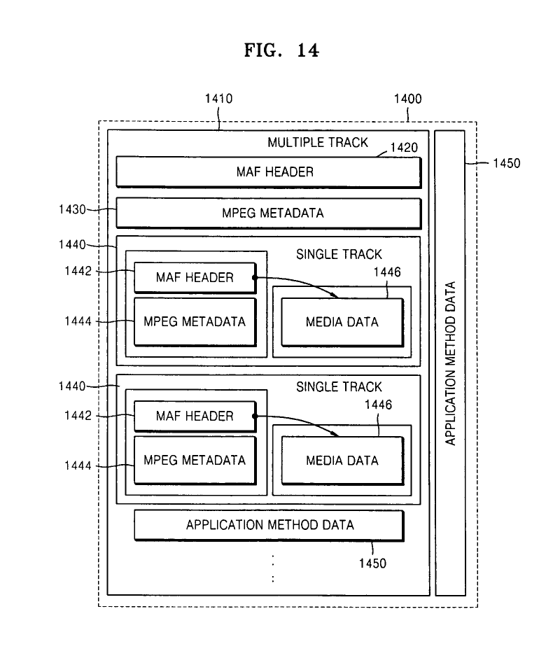

Furthermore, after creating the media metadata, an application method data creation unit 130 of FIG. 1 creates application method data 1300 of FIG. 13 for a method of utilizing media contents in operation S230. FIG. 13 is block diagram of structure of application method data 1300 according to an embodiment of the present invention.

Referring to FIG. 13, the media application method data 1300 is a major element of a media application method, and includes an MPEG-4 scene descriptor (scene description) 1310 to describe an albuming method defined by a description tool for media albuming and a procedure and method for media reproduction, and an MPEG-21 digital item processing descriptor (MPEG-21 DIP description) 1320 in relation to digital item processing (DIP) complying with a format and procedure intended for a digital item. The digital item processing descriptor includes a descriptor (MPEG-21 digital item method) 1325 for a method of basically applying a digital item. The present invention is characterized in that it includes the data as the media application method data 1300, but elements included in the media application method data 1300 are not limited to the data.

Metadata and application method data related to media data are transferred to the MAF encoding unit 140 and created as one independent MAF file 150 in operation S240.

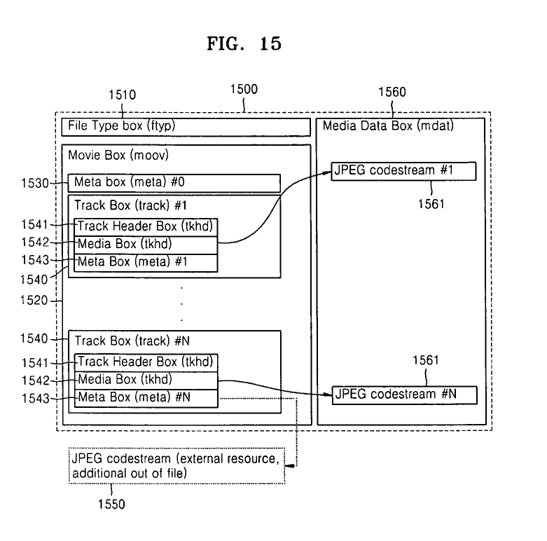

FIG. 14 illustrates a detailed structure of an MAF file 1400 according to an embodiment of the present invention. Referring to FIG. 14, the MAF file includes, as a basic element, a single track MAF 1440 which is composed of one media content and final metadata corresponding to the media content. The single track MAF 1440 includes a header (MAF header) 1442 of the track, MPEG metadata 1444, and media data 1446. The MAF header is data indicating media data, and may comply with ISO basic media file format.

Meanwhile, an MAF file can be formed with one multiple track MAF 1420 which is composed of a plurality of single track MAFs 1440. The multiple track MAF 1420 includes one or more single track MAFs 1440, an MAF header 1442 of the multiple tracks, MPEG metadata 1430 in relation to the multiple tracks, and application method data 1300, 1450 of the MAF file. In the current embodiment, the application method data 1450 is included in the multiple tracks 1410. In another embodiment, the application method data 1450 may be input independently to an MAF file.

According to the present invention, the MAF file 1400 is decoded in a decoding unit, and then transferred into a playing unit for displaying the decoded MAF file. An MAF decoding unit 160 extracts media data, media metadata, and application data from the transferred MAF file 1400, and then decodes data in operation S250. The decoded information is transferred into an MAF playing unit to be displayed to the user in operation S260. The MAF playing unit 170 includes a media metadata tool 180 for processing media metadata, and an application method tool 190 for effectively browsing media by using metadata and application data.

FIG. 15 illustrates a detailed structure of an MAF file 1400 according to another embodiment of the present invention. Referring to FIG. 15, the MAF file 1500 illustrated in FIG. 15 uses an MPEG-4 file format in order to include a JPEG resource and related metadata as in FIG. 14. Most of the elements illustrated in FIG. 15 are similar to those illustrated in FIG. 14. For example, a part (File Type box) 1510 indicating the type of a file corresponds to the MAF header 1420 illustrated in FIG. 4, and a part (Meta box) 1530 indicating metadata in relation to a collection level corresponds to MPEG metadata 1430 illustrated in FIG. 4.

Referring to FIG. 15, the MAF file 1500 is broadly composed of the part (File Type box) 1510 indicating the type of a file, a part (Movie box) 1520 indicating the metadata of an entire file, i.e., the multiple tracks, and a part (Media Data box) 1560 including internal JPEG resources as a JPEG code stream 1561 in each track.

Also, the part (Movie box) 1520 indicating the metadata of the entire file includes, as basic elements, the part (Meta box) 1530 indicating the metadata in relation to a collection level and a single track MAF (Track box) 1540 formed with one media content and metadata corresponding to the media content. The single track MAF 1540 includes a header (Track Header box) 1541 of the track, media data (Media box) 1542, and MPEG metadata (Meta box) 1543. MAF header information is data indicating media data, and may comply with an ISO basic media file format. The link between metadata and each corresponding internal resource can be specified using the media data 1542. If an external resource 1550 is used instead of the MAF file itself, link information to this external resource may be included in a position specified in each single track MAF 1540, for example, may be included in the media data 1542 or MPEG metadata 1543.

Also, a plurality of signal track MAFs 1540 may be included in the part (Movie box) 1520 indicating the metadata of the entire file. Meanwhile, the MAF file 1500 may further include data on the application method of an MAF file as illustrated in FIG. 4. At this time, the application method data may be included in multiple tracks or may be input independently into an MAF file.

Also, in the MAF file 1500, descriptive metadata may be stored using metadata 1530 and 1543 included in Movie box 1520 or Track box 1540. The metadata 1530 of Movie box 1520 can be used to define collection level information and the metadata 1543 of Track box 1540 can be used to define item level information. All descriptive metadata can be used using an MPEG-7 binary format for metadata (BiM) and the metadata 1530 and 1543 can have an mp7b handler type. The number of Meta box for collection level descriptive metadata is 1, and the number of Meta boxes for item level description metadata is the same as the number of resources in the MAF file 1500.

In addition to the above-described exemplary embodiments, exemplary embodiments of the present invention can also be implemented by executing computer readable code/instructions in/on a medium, e.g., a computer readable medium. The medium can correspond to any medium/media permitting the storing and/or transmission of the computer readable code. The computer readable code/instructions can be recorded/transferred in/on a medium in a variety of ways, with examples of the medium including magnetic storage media (e.g., floppy disks, hard disks, magnetic tapes, etc.), optical recording media (e.g., CD-ROMs, or DVDs), magneto-optical media (e.g., floptical disks), hardware storage devices (e.g., read only memory media, random access memory media, flash memories, etc.) and storage/transmission media such as carrier waves transmitting signals, which may include instructions, data structures, etc. Examples of storage/transmission media may include wired and/or wireless transmission (such as transmission through the Internet). Examples of wired storage/transmission media may include optical wires and metallic wires. The medium/media may also be a distributed network, so that the computer readable code/instructions is stored/transferred and executed in a distributed fashion. The computer readable code/instructions may be executed by one or more processors.

According to the present invention as described above, in a process of integrating digital photos and other multimedia content files into one file in the application file format MAF, visual feature information obtained from photo data and the contents of the photo images, and a variety of hint feature information for effective indexing of photos are included as metadata and content application method tools based on the metadata are included. Accordingly, even when the user does not have a specific application or a function for applying metadata, general-purpose multimedia content files can be effectively used by effectively browsing the multimedia content files.

Although a few exemplary embodiments of the present invention have been shown and described, it would be appreciated by those skilled in the art that changes may be made in these exemplary embodiments without departing from the principles and spirit of the invention, the scope of which is defined in the claims and their equivalents.

What is claimed is:

1. A method of encoding multimedia contents, comprising:
separating media data and metadata from multimedia contents;
creating metadata complying with a predetermined multimedia application format (MAF) by using the separated metadata; and
encoding the media data and the metadata complying with the standard format, and thus creating an MAF file including a header containing information indicating a location of the media data, the metadata and the media data.

2. The method of claim 1, further comprising obtaining multimedia data from a multimedia apparatus before the separating of the media data and the metadata from the multimedia contents.

3. The method of claim 2, wherein the multimedia contents comprise photos acquired from a photo content acquiring apparatus and music and video data related to the photos.

4. The method of claim 1, wherein the separating of the media data and the metadata from multimedia contents comprises extracting information required to generate metadata related to a corresponding media content by parsing exchangeable image file format (Exif) metadata or decoding a joint photographic experts group (JPEG) image included in the multimedia contents.

5. The method of claim 4, wherein the metadata comprises Exif metadata of a JPEG photo file, ID3 metadata of an MP3 music file, and compression related metadata of an MPEG video file.

6. The method of claim 1, wherein in the creating of the metadata complying with a predetermined standard format, the metadata complying with an MPEG standard is created from the separated metadata, or the metadata complying with an MPEG standard is created by extracting and creating metadata from the media content by using an MPEG-based standardized description tool.

7. The method of claim 6, wherein the metadata complying with an MPEG standard comprises MPEG-7 metadata for a media content itself, and MPEG-21 metadata for declaration, adaptation conversion, and distribution of the media content.

8. The method of claim 7, wherein the MPEG-7 metadata comprises MPEG-7 descriptors of metadata for media content-based feature values, MPEG-7 semantic descriptors of metadata for media semantic information, and MPEG-7 media information/creation descriptors of media creation information.

9. The method of claim 8, wherein the MPEG-7 media information/creation descriptors comprise media albuming hints.

10. The method of claim 9, wherein the media albuming hints comprises acquisition hints expressing camera information and photographing information when a photo is taken, perception hints expressing perceptional characteristics of a human being in relation to the contents of a photo, view hints expressing view information of a camera, subject hints expressing information on persons included in a photo, and popularity expressing popularity information of a photo.

11. The method of claim 10, wherein the acquisition hints expressing camera information and photographing information when a photo is taken comprises:
at least one of information on the photographer who takes a photo, time information on the time when a photo is taken, manufacturer information on the manufacturer of the camera with which a photo is taken, camera model information of a camera with which a photo is taken, shutter speed information of a shutter speed used when a photo is taken, color mode information of a color mode used when a photo is taken, information indicating the sensitivity of a film when a photo is taken, information indicating whether or not a flash is used when a photo is taken, information indicating the aperture number of a lens iris used when a photo is taken, information indicating the optical zoom distance used when a photo is taken, information indicating the focal length used when a photo is taken, information indicating the distance between the focused-upon subject and the camera when a photo is taken, global positioning system (GPS) information on a place where a photo is taken, information indicating the orientation of a first pixel of a photo image as the orientation of a camera when the photo is taken, information indicating sound recorded together when a photo is taken, and information indicating a thumbnail image stored for high-speed browsing in a camera after a photo is taken; and
information indicating whether or not the photo data includes Exif information as metadata.

12. The method of claim 10, wherein the perception hints expressing perceptional characteristics of a human being in relation to the contents of a photo comprises at least one of:
an item (avgcolorfulness) indicating the colorfulness of the color tone expression of a photo;
an item (avgColorCoherence) indicating the color coherence of the entire color tone appearing in a photo;
an item (avgLevelOfDetail) indicating the detailedness of the contents of a photo;
an item (avgHomogenity) indicating the homogeneity of texture information of the contents of a photo;
an item (avgPowerOfEdge) indicating the robustness of edge information of the contents of a photo;
an item (avgDepthOfField) indicating the depth of the focus of a camera in relation to the contents of a photo;
an item (avgBlurrness) indicating the blurriness of a photo caused by shaking of a camera generally due to a slow shutter speed;
an item (avgGlareness) indicating the degree that the contents of a photo are affected by a very bright flash light or a very bright external light source when the photo is taken; and
an item (avgBrightness) indicating information on the brightness of an entire photo.

13. The method of claim 12, wherein the avgcolorfulness item indicating the colorfulness of the color tone expression of a photo is measured after normalizing the histogram heights of each RGB color value and the distribution value of the entire color values from a color histogram, or by using the distribution value of a color measured using a CIE L*u*v color space.

14. The method of claim 12, wherein the avgColorCoherence item indicating the color coherence of the entire color tone appearing in a photo can be measured by using a dominant color descriptor from among the MPEG-7 visual descriptors, and is measured by normalizing the histogram heights of each color value and the distribution value of the entire color values from a color histogram.

15. The method of claim 12, wherein the avgLevelOfDetail item indicating the detailedness of the contents of a photo is measured by using an entropy measured from the pixel information of the photo, or by using an isopreference curve that is an element for determining the actual complexity of a photo, or by using a relative measurement method in which compression ratios are compared when compressions are performed under identical compression conditions.

16. The method of claim 12, wherein the avgHomogenity item indicating the homogeneity of texture information of the contents of a photo is measured by using the regularity, direction and scale of texture from feature values of a texture browsing descriptor among the MPEG-7 visual descriptors.

17. The method of claim 12, wherein the avgPowerOfEdge item indicating the robustness of edge information of the contents of a photo is measured by extracting edge information from a photo and normalizing the extracted edge power.

18. The method of claim 12, wherein the avgDepthOfField item indicating the depth of the focus of a camera in relation to the contents of a photo is measured by using the focal length and diameter of a camera lens, and an iris number.

19. The method of claim 12, wherein the avgBlurrness item indicating the blurriness of a photo caused by shaking of a camera due to a slow shutter speed is measured by using the edge power of the contents of the photo.

20. The method of claim 12, wherein the avgGlareness item indicating the degree that the contents of a photo are affected by a very bright external light source is measured by using the brightness of the pixel value of the photo.

21. The method of claim 12, wherein the avgBrightness item indicating information on the brightness of an entire photo is measured by using the brightness of the pixel value of the photo.

22. The method of claim 10, wherein the subject hints expressing information on persons included in a photo comprises:
an item indicating the number of persons included in a photo;
an item indicating the position of the face of each person and the position of clothes worn by the person; and
an item indicating the relationship between persons included in a photo.

23. The method of claim 22, wherein the item indicating the position information of the face and clothes of each person included in a photo comprises an ID, the face position, and the position of clothes of the person.

24. The method of claim 22, wherein the item indicating the relationship between persons included in a photo comprises an item indicating a first person of the two person in the relationship, an item indicating the second person, and an item indicating the relationship between the two persons.

25. The method of claim 10, wherein the view hints expressing the view information of the photo comprises:
an item indicating whether the main subject of a photo is a background or a foreground;
an item indicating the position of a part corresponding to the background of a photo in the contents expressed in the photo;
an item indicating the position of a part corresponding to the background of a photo.

26. The method of claim 7, wherein the MPEG-21 metadata comprises an MPEG-21 DID (digital item declaration) description that is metadata related to a DID, an MPEG-21 DIA (digital item adaptation) description that is metadata for a DIA, and rights expression data that is metadata regarding rights/copyrights of contents.

27. The method of claim 26, wherein the rights expression data comprises a browsing permission that is metadata of permission information of browsing photo contents, and an editing permission that is metadata of permission information of editing photo contents.

28. The method of claim 1, further comprising creating MAF application method data, wherein in the encoding of the media data and the metadata complying with the standard format, and thus the creating of the MAF file, the MAF file including the header containing information indicating the media data, the metadata and the media data is created using the media data, the metadata complying with the standard format, and the MAF application method data.

29. The method of claim 28, wherein the MAF application method data comprises:
an MPEG-4 scene descriptor for the MAF application method data for describing an albuming method defined by a media albuming tool and a procedure and method for media reproduction; and
an MPEG-21 DIP descriptor for processing a digital item according to an intended format and procedure.

30. The method of claim 1 or 29, wherein in the encoding of the media data and the metadata complying with the standard format, and thus the creating of the MAF file, the MAF file comprises a single track MAF as a basic element, in which the single track MAF is formed with one media content and corresponding metadata, and the single track MAF comprises a header related to the track, MPEG metadata, and media data.

31. The method of claim 1, wherein in the encoding of the media data and the metadata complying with the standard format, and thus the creating of the MAF file, the MAF file comprises a multi-track MAF including one or more single track MAFs, an MAF header related to the multiple tracks and MPEG metadata for the multiple tracks.

32. The method of claim 30, wherein in the encoding of the media data and the metadata complying with the standard format, and thus the creating of the MAF file, the MAF file comprises a multi-track MAF including one or more single track MAFs, an MAF header related to the multiple tracks, MPEG metadata for the multiple tracks, and data on the application method of the MAF file.

33. The method of claim 8, wherein the MPEG-7 semantic descriptors extract and generate semantic information of the multimedia contents using albuming hints.

34. The method of claim 33, wherein the extracting of the semantic information comprises performing media albuming by using media albuming hints or using the media albuming hints and the contents-based feature values.

35. The method of claim 3, wherein the performing of media albuming by using media albuming hints comprises performing indexing or clustering of an arbitrary j-th content mⱼ using albuming hints, which is expressed in the following Equation, where a boolean function B(a,b)=1 when a=b, and otherwise 0, and Lⱼ represents a j-th content mⱼ label.

36. The method of claim 35, wherein the performing of the media albuming by using a combination of the media albuming hints and the contents-based feature values comprises combining albuming hints Hⱼ of an arbitrary j-th content mⱼ and contents-based feature values Fⱼ to create a combined new feature values, the combined new feature values Fⱼ′ being expressed in the following Equation, where represents an arbitrary function combining the contents-based feature values and the albuming hints.

37. The method of claim 35, wherein the performing of the media albuming by using a combination of the media albuming hints and the contents-based feature values comprises obtaining a similarity value by comparing an feature value that is learned from an albuming label set G, and determining a label with the largest similarity value as a label of a j-th content mⱼ, the determining of the label of the j-th content mⱼ expressed in the following Equation.

38. A method of playing multimedia contents, comprising:
decoding an MAF file including a header and application data to extract media data, media metadata, and application data, the header having information that provides a location of media data, the application data providing media application method information having at least one single track with media data and media metadata; and
playing the multimedia contents using the extracted metadata and the application data.

39. The method of claim 38, wherein the playing of the multimedia contents comprises using media metadata tools for processing media metadata and application method tools for browsing the media contents through metadata and application data.

40. An apparatus for encoding multimedia contents, comprising:
a pre-processing unit separating media data and metadata from multimedia contents;
a media metadata creation unit creating MAF metadata by using the separated metadata, the format of the MAF metadata being predetermined; and
an encoding unit encoding the media data and the MAF metadata to generate an MAF file including a header, the MAF metadata, and the media data, the header having information that provides a location of the media data.

41. The apparatus of claim 40, further comprising a media acquisition/input unit acquiring multimedia contents from a multimedia device or having multimedia contents input from a multimedia device.

42. The apparatus of claim 41, wherein the multimedia contents comprise photos acquired from a photo content acquiring apparatus and music and video data related to the photos.

43. The apparatus of claim 40, wherein the pre-processing unit extracts information required to generate metadata related to a corresponding media content by parsing exchangeable image file format (Exif) metadata or decoding a joint photographic experts group (JPEG) image included in the multimedia contents.

44. The apparatus of claim 40, wherein the media metadata creation unit creates the metadata complying with an MPEG standard from the separated metadata, or the metadata complying with an MPEG standard by extracting and creating metadata from the media content by using an MPEG-based standardized description tool.

45. The apparatus of claim 44, wherein the metadata compatible with the MPEG standard comprises MPEG-7 metadata for a media content, and MPEG-21 metadata for declaration, adaptation conversion, and distribution of the media content.

46. The apparatus of claim 7, wherein the MPEG-7 metadata comprises MPEG-7 descriptors of metadata for media content-based feature values, MPEG-7 semantic descriptors of metadata for media semantic information, and MPEG-7 media information/creation descriptors of media creation information.

47. The apparatus of claim 46, wherein the MPEG-7 media information/creation descriptors comprise media albuming hints.

48. The apparatus of claim 46, wherein the MPEG-21 metadata comprises an MPEG-21 DID description that is metadata related to a DID, an MPEG-21 DIA description that is metadata for a DIA, and rights expression data that is metadata regarding rights/copyrights of contents.

49. The apparatus of claim 40, further comprising an application method data creation unit that creates MAF application method data, wherein the encoding unit creates an MAF file including a header, metadata, and media data using the media data, the MAF metadata, and the MAF application method data, the header having information that provides a location of the media data.

50. The apparatus of claim 49, wherein the MAF application method data comprises:
an MPEG-4 scene description describing an albuming method defined by a media albuming tool, and a procedure and a method for media playing; and
an MPEG-21 digital item processing (DIP) descriptor for DIP according to an intended format and procedure.

51. The apparatus of claim 40 or 50, wherein the MAF file comprises a single track MAF as a basic element, in which the single track MAF is formed with one media content and corresponding metadata, and the single track MAF comprises a header related to the track, MPEG metadata, and media data.

52. The apparatus of claim 40, wherein the MAF file comprises a multi-track MAF including one or more single track MAFs, an MAF header related to the multiple tracks and MPEG metadata for the multiple tracks.

53. The apparatus of claim 51, wherein the MAF file comprises a multi-track MAF including one or more single track MAFs, an MAF header related to the multiple tracks, MPEG metadata for the multiple tracks, and data on the application method of the MAF file.

54. An apparatus for playing multimedia contents, comprising:
an MAF decoding unit decoding an MAF file including a header having information that provides a location of media data, at least one single track having media data and media metadata, and application data representing media application method information to extract the media data, media metadata, and the application data; and
an MAF playing unit playing the multimedia contents by using the extracted metadata and application data.

55. The apparatus of claim 54, further comprising media metadata tools for processing media metadata and application method tools for browsing the multimedia contents by using the metadata and the application data.

56. An MAF comprising a single track MAF corresponding to one media content, the single track MAF including an MAF header for a corresponding track, MPEG metadata, and media data.

57. An MAF comprising a multi-track MAF including one or more single track MAFs, an MAF header related to the multiple tracks, and MPEG metadata for the multiple tracks.

58. The MAF of claim 57, further comprising application method data for an application method of an MAF file.

59. A computer-readable recording medium comprising a computer-readable program for executing the method of any one of claims 1 to 39.
